(19) United States
(12) Patent Application Publication
(10) Pub. No.: US 2026/0095122 A1
(43) Pub. Date: Apr. 2, 2026

(54) SOLAR SILICON WAFER INSPECTION ALL-IN-ONE MACHINE

(71) Applicant: Guangdong Kelongwei Automation Equipment Co., Ltd., Dongguan (CN)

(72) Inventors: Jincai SU, Dongguan (CN); Chunfu CHEN, Dongguan (CN)

(21) Appl. No.: 19/403,146

(22) Filed: Nov. 27, 2025

(30) Foreign Application Priority Data
Nov. 27, 2024 (CN) 202411717662.0
Nov. 27, 2024 (CN) 202411717664.X

(51) Int. Cl. H02S 50/10; G01R 31/28

(52) U.S. Cl. CPC H02S 50/10; G01R 31/2868

(57) ABSTRACT

The present invention discloses a solar silicon wafer inspection all-in-one machine, comprising a front-end conveying rail, an AOI detection mechanism and an IV detection mechanism, wherein the AOI detection mechanism is positioned between the front-end conveying rail and the IV detection mechanism; at least one segment of silicon wafer conveying rail is arranged on the front-end conveying rail; the AOI detection mechanism includes a four-position turntable, a back AOI detection instrument assembly, a front AOI detection instrument assembly and an AOI detection conveying rail; the IV detection mechanism includes a working platform, an indexing disc assembly and at least one detection mechanism. This solar silicon wafer inspection all-in-one machine is designed for conveying silicon wafers, successively undergoing AOI inspection and IV inspection. Operating automatically, it precisely connects the probe to the grid lines on the silicon wafers, enhancing inspection efficiency and increasing productivity.

### CROSS-REFERENCE TO RELATED APPLICATIONS

This application claims the benefit of priority from Chinese Patent Application No. 202411717664.X, filed on November 27, 2024; and Chinese Patent Application No. 202411717662.0, filed on November 27, 2024. The content of the aforementioned applications, including any intervening amendments thereto, is incorporated herein by reference.

### TECHNICAL FIELD

The present invention relates to the technical field of silicon wafer production, particularly to a solar silicon wafer inspection all-in-one machine.

### BACKGROUND

After printing, crystalline silicon photovoltaic solar silicon wafer is subject to AOI inspection and IV inspection. The full name of AOI inspection in Chinese is automatic optical inspection, and the device detects common defects encountered in printing production based on optical principle.IV inspection refers to the current-voltage characteristic curve (IV curve) testing of photovoltaic modules, and only the silicon wafer tested as good can enter the next production process device. The existing silicon wafer needs multiple devices to cooperate in the AOI inspection and IV inspection. This affects the docking process before and after inspection and processing, and the productivity is relatively low.

### SUMMARY

An objective of present invention is to provide a solar silicon wafer inspection all-in-one machine. The machine can detect silicon wafers, integrate AOI detection and IV detection, save processes and steps, and improve the detection productivity.

To achieve this objective, the present invention employs the following technical solutions:

A solar silicon wafer inspection all-in-one machine, wherein it comprises a front-end conveying rail, an AOI detection mechanism and an IV detection mechanism, and the AOI detection mechanism is positioned between the front-end conveying rail and the IV detection mechanism;

The front-end conveying rail is provided with at least one segment of silicon wafer conveying rail, and the silicon wafer conveying rail is used for conveying silicon wafers.

The AOI inspection mechanism comprises a four-position turntable, a back AOI inspection instrument assembly, a front AOI inspection instrument assembly and an AOI inspection conveying rail. The four-position turntable is located at the front end of the AOI inspection conveying rail, and the back AOI inspection instrument assembly is located below the front end of the four-position turntable. The front AOI detection instrument assembly is installed above the AOI detection conveying rail.

The IV detection mechanism comprises a working platform, an indexing disc assembly and at least one set of detection mechanism. The indexing disc assembly is located in the middle of the working platform, and the detection mechanism is located in front of the indexing disc assembly. The detection mechanism includes a UVW base, an upper probe holder and a lower probe holder. The lower end of the UVW base is installed with a UVW correction alignment assembly. The UVW correction alignment assembly includes two sets of X-axis modules and one set of Y-axis modules. The upper probe holder and the lower probe holder move vertically on the UVW base respectively and the detection probes are installed on the upper probe holder and/or the lower probe holder.

As a preferred technical solution, a temporary storage linear module is arranged on the front-end conveying rail, a temporary storage frame is arranged at the driving end of the temporary storage linear module, and the temporary storage frame moves laterally on the side of the silicon wafer conveying rail.

As a preferred technical solution, the front-end conveying rail is provided with a feeding linear module, and the driving end of the feeding linear module is connected with a feeding longitudinal module. The feeding longitudinal module moves laterally on the side of the silicon wafer conveying rail, the driving end of the feeding longitudinal module is connected with a feeding rack, and the feeding rack moves up and down in the vertical direction.

As a preferred technical solution, a clamp plate positioning mechanism is arranged in the middle of the silicon wafer conveying rail, and the clamp plate positioning mechanism comprises a clamp plate positioning motor, a clamp plate positioning synchronous belt and a clamp plate positioning support; the driving end of the clamp plate positioning motor is connected with a clamp plate positioning wheel; the clamp plate positioning synchronous belt is in transmission connection with the clamp plate positioning wheel and the clamp plate positioning support is installed on the clamp plate positioning synchronous belt.

As a preferred technical solution, the front end of the silicon wafer conveying rail is provided with an air-blowing cooling pipe, and the rear end of the silicon wafer conveying rail is provided with an ion antistatic air knife.

As a preferred technical solution, an AOI shaft is arranged above the four-position turntable, and four AOI adsorption modules are arranged on the periphery of the four-position turntable.

As a preferred technical solution, both sides of the indexing disc assembly are respectively provided with a front track and a rear track, and both the front track and the rear track drive a track belt through a track motor to convey silicon wafers.

As a preferred technical solution, a first walking arm and a second walking arm are respectively installed on both sides of the front track and the side edge of the rear track, and a walking linear module is arranged on both the first walking arm and the second walking arm, and a moving plate is connected to the driving end of the walking linear module, and a negative pressure adsorption plate is fixed to the inner end of the moving plate.

As a preferred technical solution, the X-axis module and the Y-axis module both comprise a motor mounting base, a module motor, an adjusting screw rod and an adjusting sliding table. The module motor is fixed on the motor mounting base, the driving end of the module motor is in transmission connection with the adjusting screw rod, and the adjusting screw rod is in threaded connection with the adjusting nut of the adjusting sliding table. The adjusting sliding table slides along the length direction of the adjusting screw rod, and the adjusting sliding table is provided with a connecting bearing; the connecting bearing slides on the adjusting sliding table, the moving direction of the connecting bearing is perpendicular to that of the adjusting sliding table, and the edge of the UVW base is locked in the connecting bearing; two sets of X-axis modules and one set of Y-axis modules jointly control the T-axis rotation of the UVW base on one side.

As a preferred technical solution, the UVW base is provided with an upper linear module and a lower linear module. The upper linear module controls the vertical movement of the upper probe holder and the lower linear module controls the vertical movement of the lower probe holder.

As a preferred technical solution, the silicon wafer conveying rail is a single-cell conveying rail, and the single-cell conveying rail is used for conveying single-cell silicon wafers.

As a preferred technical solution, the silicon wafer conveying rail comprises two segments of half-cell conveying rails. The two segments of half-cell conveying rails are arranged side by side on the front-end conveying rail and used for conveying double half-cell silicon wafers.

The beneficial effects of the present invention are as follows: A solar silicon wafer inspection all-in-one machine is provided for conveying silicon wafers, successively undergoing AOI inspection and IV inspection.Operating automatically, it precisely connects the probe to the grid lines on the silicon wafers, enhancing inspection efficiency and increasing production capacity. The all-in-one multi-functional structure meets the demands of both front-end and back-end production.

### BRIEF DESCRIPTION OF THE DRAWINGS

The present invention will now be described in further detail with reference to the drawings and embodiments.

FIG. 1 is an overall structural diagram of the solar silicon wafer inspection all-in-one machine according to Embodiment 1;

FIG. 2 is a structural diagram of the front-end conveying rail according to Embodiment 1;

FIG. 3 is a structural diagram of the air-blowing cooling pipe according to Embodiment 1;

FIG. 4 is a structural diagram of the clamp plate positioning mechanism according to Embodiment 1;

FIG. 5 is a structural diagram of the ion antistatic air knife according to according to Embodiment 1;

FIG. 6 is a structural diagram of the AOI detection mechanism according to Embodiment 1;

FIG. 7 is a structural diagram of the IV detection mechanism according to Embodiment 1;

FIG. 8 is a structural diagram of the X-axis module (or Y-axis module) according to Embodiment 1;

FIG. 9 is a structural diagram of the upper probe holder according to Embodiment 1;

FIG. 10 is a structural diagram of the lower probe holder according to Embodiment 1;

FIG. 11 is an overall structural diagram of the solar silicon wafer inspection all-in-one machine according to Embodiment 2;

FIG. 12 is a structural diagram of the front-end conveying rail according to Embodiment 2;

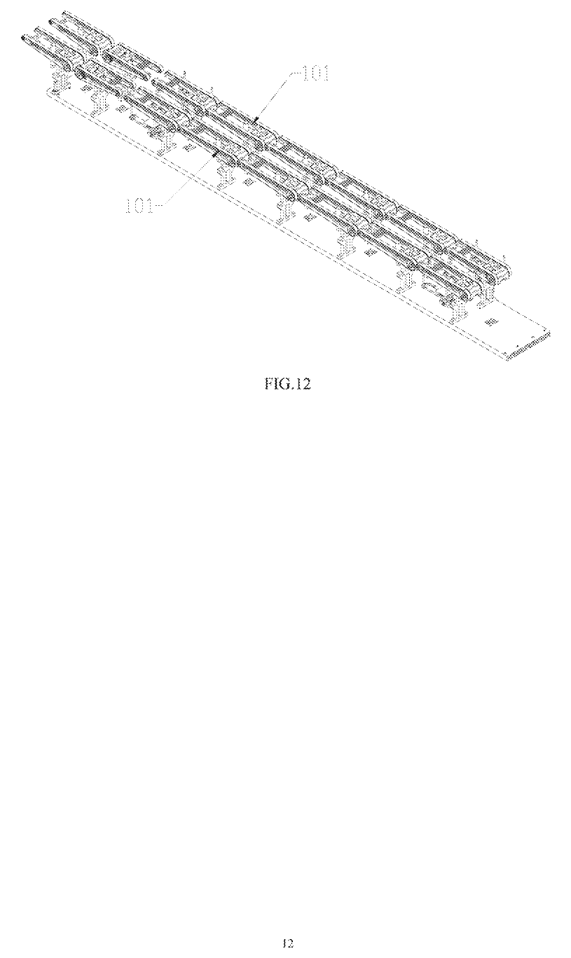

FIG. 13 is a structural diagram of the air-blowing cooling pipe according to Embodiment 2;

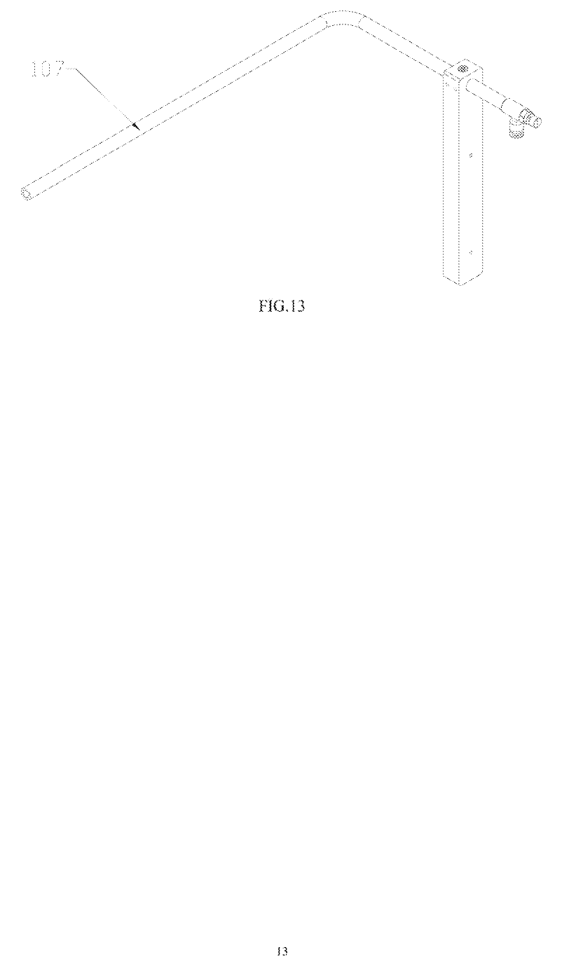

FIG. 14 is a structural diagram of the clamp plate positioning mechanism according to Embodiment 2;

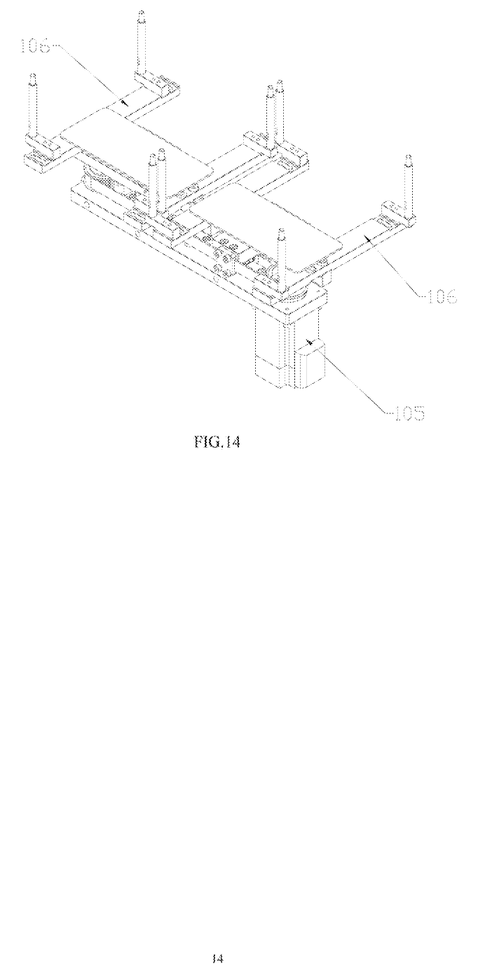

FIG. 15 is a structural diagram of the ion antistatic air knife according to according to Embodiment 2;

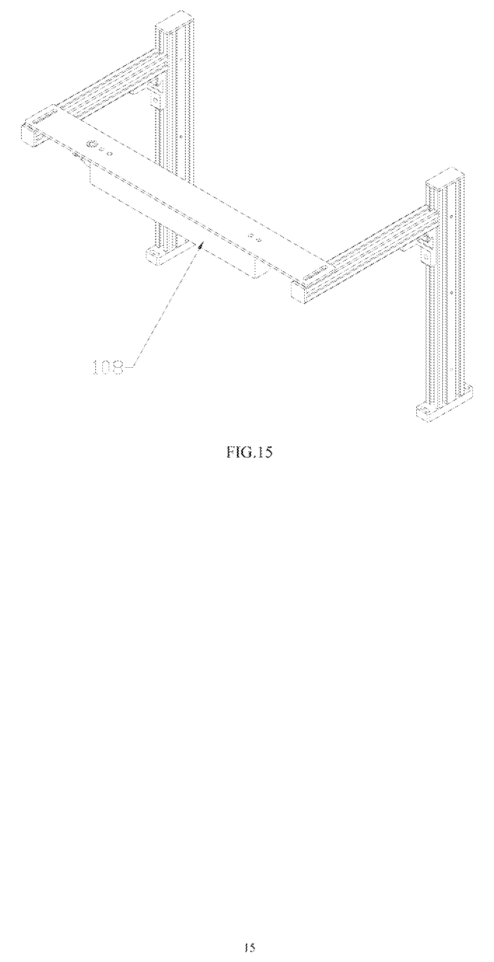

FIG. 16 is a structural diagram of the AOI detection mechanism according to Embodiment 2;

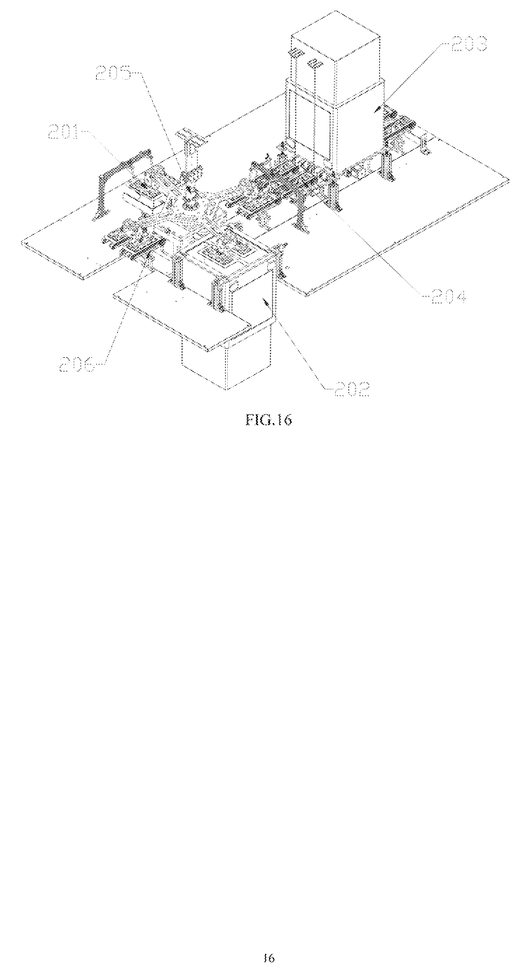

FIG. 17 is a structural diagram of the IV detection mechanism according to Embodiment 2;

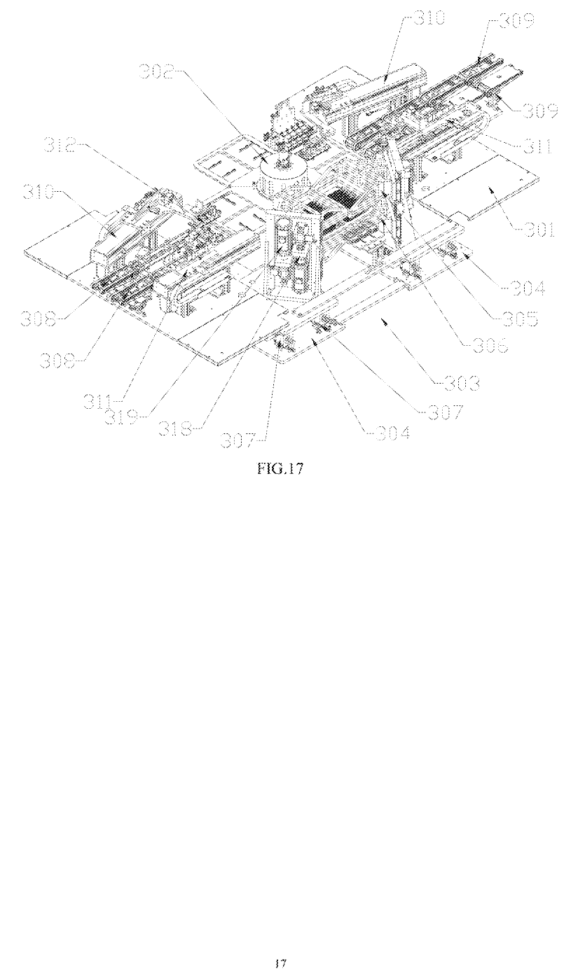

FIG. 18 is a structural diagram of the X-axis module (or Y-axis module) according to Embodiment 2;

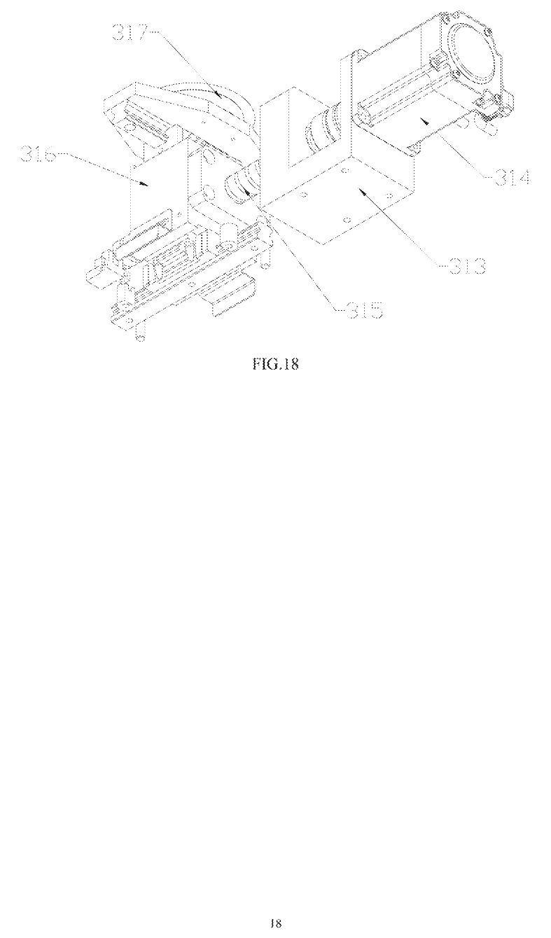

FIG. 19 is a structural diagram of the lower probe holder according to Embodiment 2;

1. Front-end conveying rail; 101. Silicon wafer conveying rail; 102. Temporary frame; 103. Feeding rack; 104. Clamp plate positioning mechanism; 105. Clamp plate positioning motor; 106.Clamp plate positioning support; 107.Air-blowing cooling pipe; 108.Ion antistatic air knife;

2. AOI detection mechanism; 201. Four-position turntable; 202. Back AOI detection instrument assembly; 203. Front AOI detection instrument assembly; 204. AOI detection conveying rail; 205. AOI shaft; 206. AOI adsorption module;

3. IV detection mechanism; 301.Working platform; 302. Indexing disc assembly; 303. Detection mechanism; 304. UVW base; 305. Upper probe holder; 306. Lower probe holder; 307.X-axis module; 308.Front track; 309. Rear track; 310.First walking arm; 311. Second walking arm; 312. Moving plate; 313. Motor mounting base; 314. Module motor; 315. Adjusting screw rod; 316. Adjusting sliding table; 317. Connecting bearing; 318. Upper linear module; 319. Lower linear module.

### DETAILED DESCRIPTION OF EMBODIMENTS

The technical solution of the present invention will be further explained by specific embodiments with reference to the attached drawings.

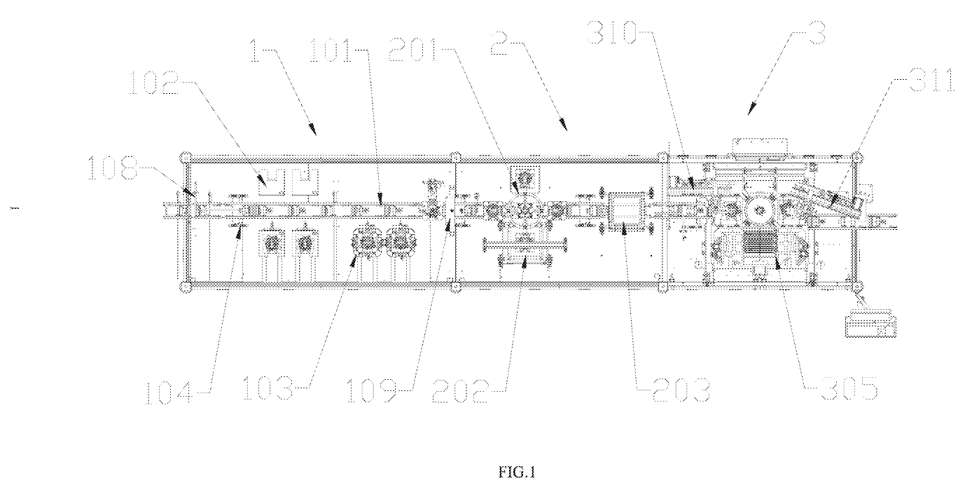

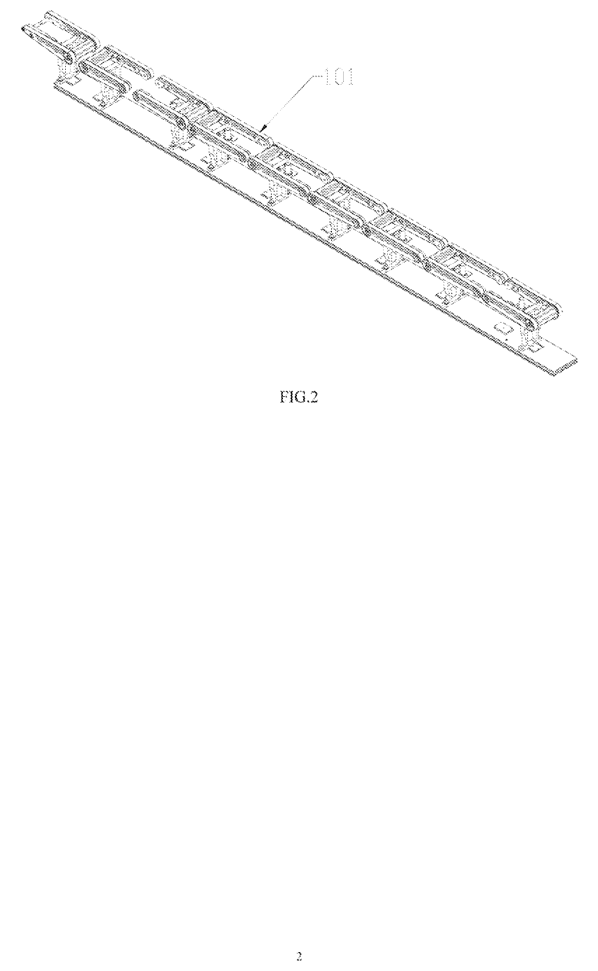

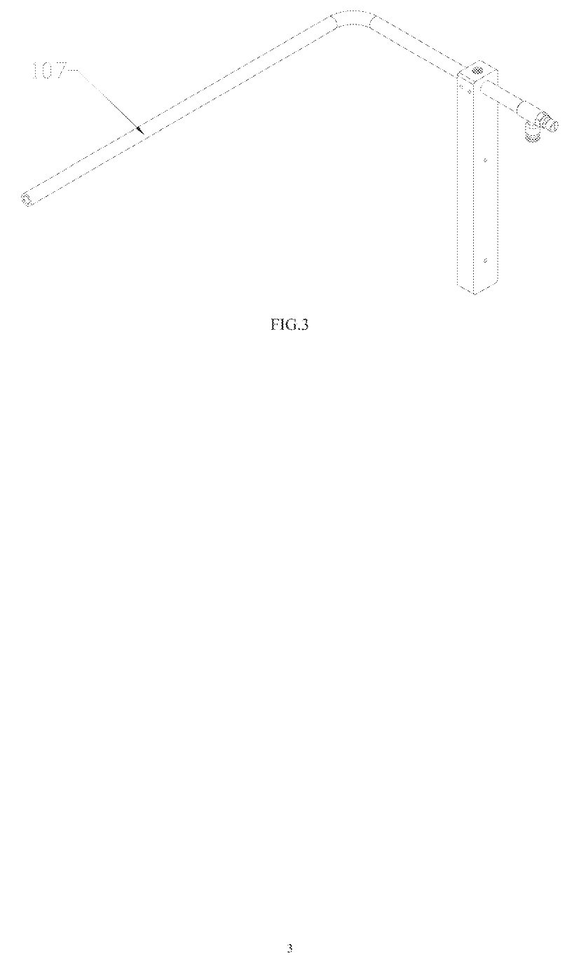

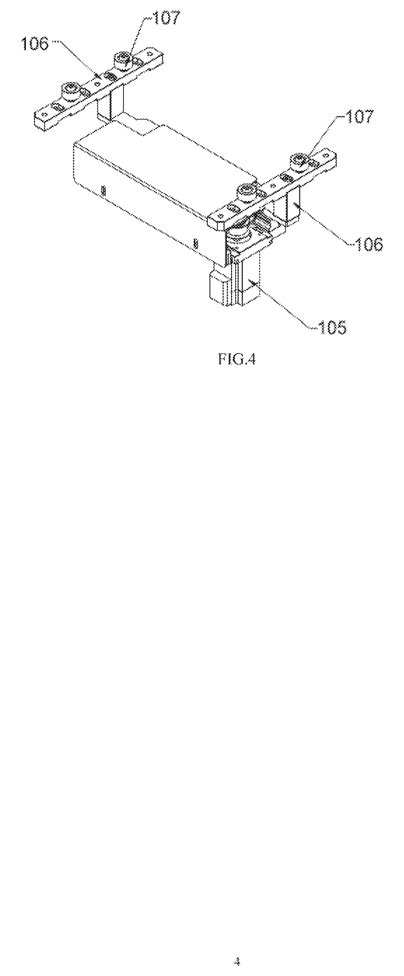

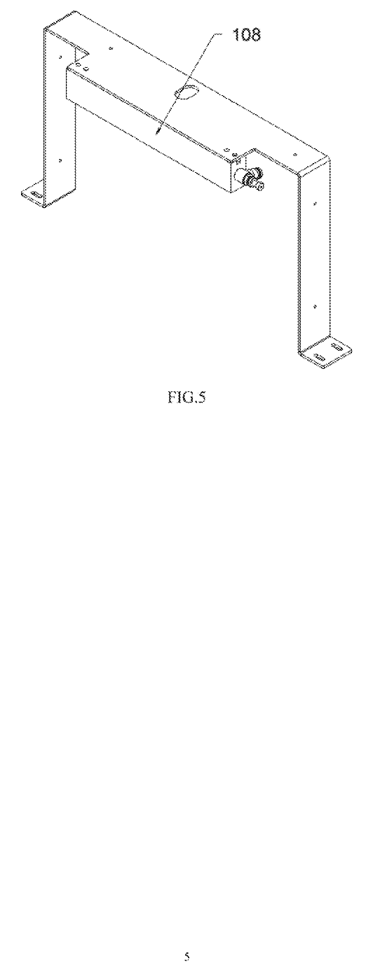

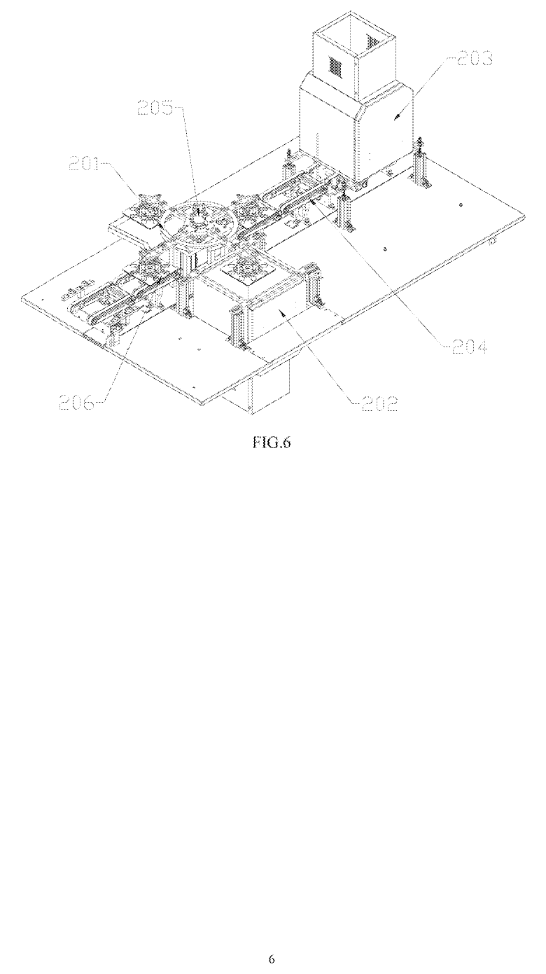

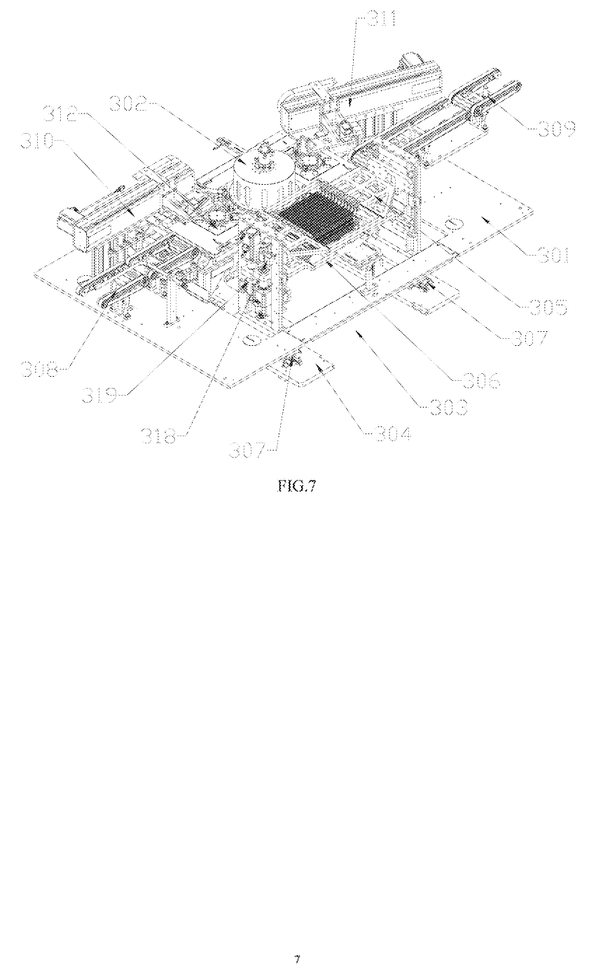

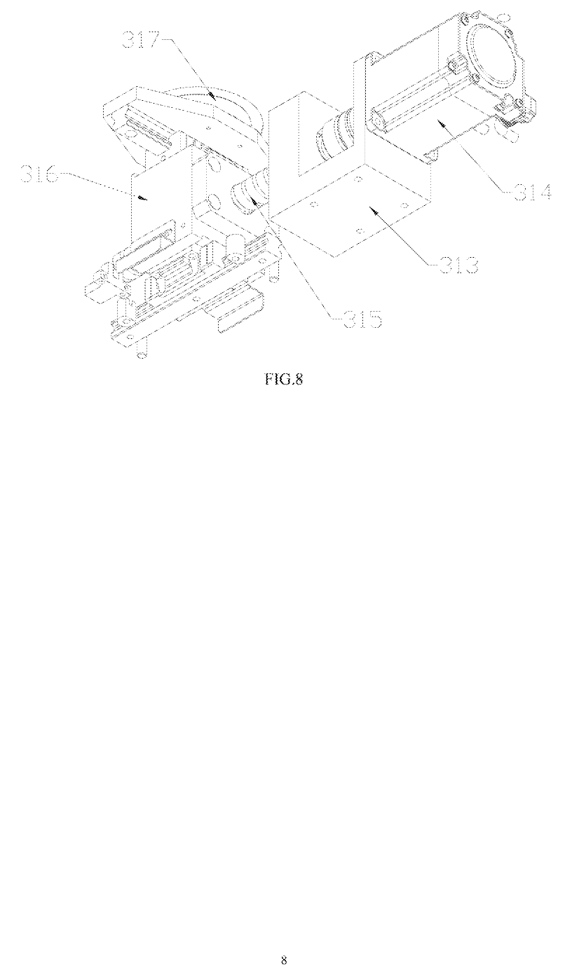

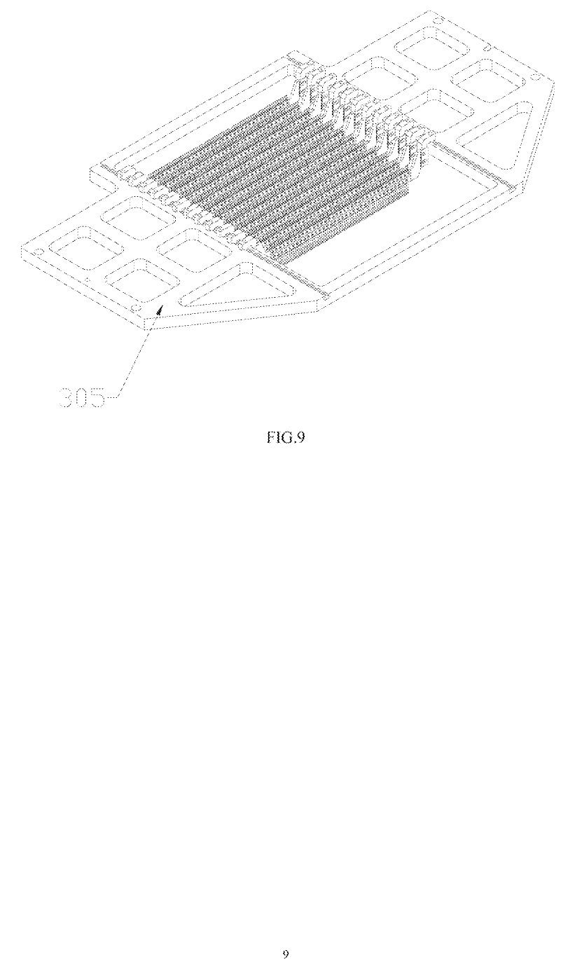

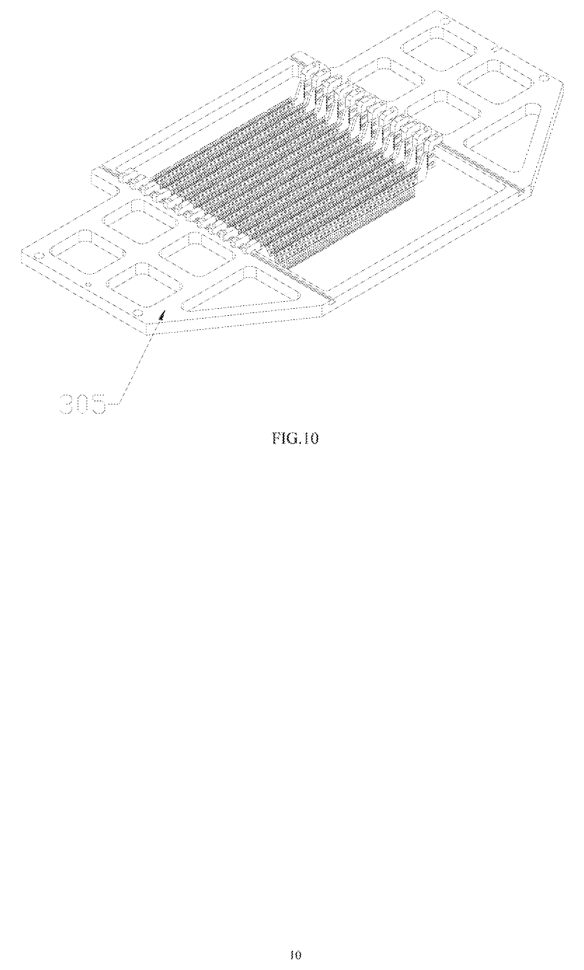

As shown in FIG.1 to FIG.10, in Embodiment 1, a solar silicon wafer inspection all-in-one machine is used for detecting single-cell silicon wafers. The solar silicon wafer inspection all-in-one machine comprises a front-end conveying rail 1, an AOI detection mechanism 2 and an IV detection mechanism 3, wherein the AOI detection mechanism 2 is located between the front-end conveying rail 1 and the IV detection mechanism 3.

Specifically, the front-end conveying rail 1 is provided with a silicon wafer conveying rail 101, the silicon wafer conveying rail is a single-cell conveying rail for conveying a single-cell silicon wafer; the AOI detection mechanism 2 comprises a four-position turntable 201, a back AOI detection instrument assembly 202, a front AOI detection instrument assembly 203 and an AOI detection conveying rail 204, wherein the four-position turntable 201 is located at the front end of the AOI detection conveying rail 204, the back AOI detection instrument assembly 202 is located below the front end of the four-position turntable 201, and the front AOI detection instrument assembly 203 is installed above the AOI detection conveying rail 204; the IV detection mechanism 3 comprises a working platform 301, an indexing disc assembly 302 and a set of detection mechanisms 303, wherein the indexing disc assembly 302 is located in the middle of the working platform 301, the detection mechanism 303 is located in front of the indexing disc assembly 302, and the detection mechanism 303 comprises a UVW base 304, an upper probe holder 305 and a lower probe holder 306, and the lower end of the UVW base 304 is provided with a UVW correction alignment assembly. The UVW correction alignment assembly includes two sets of X-axis modules 307 and one set of Y-axis modules. The upper probe holder 305 and the lower probe holder 306 respectively move on the UVW base 304 along the vertical direction, and detection probes are installed on the upper probe holder 305 and the lower probe holder 306.

After coming out of the sintering furnace, the printed single-cell silicon wafer enters the silicon wafer conveying rail 101.At the end of the silicon wafer conveying rail 101, the AOI inspection mechanism 2 grabs the single-cell silicon wafer onto the back AOI inspection instrument assembly 202 through the four-position turntable 201 for back inspection, and then turns to the AOI inspection conveying rail 204. The AOI inspection conveying rail 204 conveys the single-cell silicon wafer to the front AOI inspection instrument assembly 203 for front inspection. Then, the indexing disc assembly 302 on the IV inspection mechanism 3 controls the single-cell silicon wafer to reach the inspection mechanism 303, and under the joint action of two sets of X-axis modules 307 and one set of Y-axis modules, the lower probe holder 306 and the upper probe holder 305 on the UVW base 304 are controlled to align with the position of the single-cell silicon wafer for IV inspection.

A temporary storage linear module is arranged on the front-end conveying rail 1, and a temporary storage frame 102 is arranged at the driving end of the temporary storage linear module. The temporary storage frame 102 moves laterally on the side of the silicon wafer conveying rail 101, and the temporary storage frame 102 moves laterally on the side of the front-end conveying rail 1. When the temporary storage linear module on one side is fully loaded, the other side begins to be placed, and the fully loaded side can be manually discharged.

The front-end conveying rail 1 is provided with a feeding linear module, and the driving end of the feeding linear module is connected with a feeding longitudinal module, wherein the feeding longitudinal module moves laterally on the side of the silicon wafer conveying rail 101, and the driving end of the feeding longitudinal module is connected with a feeding rack 103, and the feeding rack moves up and down in the vertical direction. After the feeding linear module approaches the front-end conveying rail 1, the upper and lower transverse modules above the front-end conveying rail 1 control the upper and lower adsorption modules to suck up the single-cell silicon wafer on the feeding rack 103 and put it into the front-end conveying rail 1. In order to ensure the height of the uppermost silicon wafer, the feeding longitudinal module controls the feeding rack 103 to raise a silicon wafer position until all the silicon wafers on the feeding rack 103 are taken away, and the feeding linear module leaves the front-end conveying rail 1 laterally, and then repeatedly approaches the front-end conveying rail 1 for feeding after filling the silicon wafer.

A clamp plate positioning mechanism 104 is arranged in the middle of the silicon wafer conveying rail 101. The clamp plate positioning mechanism 104 comprises a clamp plate positioning motor 105, a clamp plate positioning synchronous belt and a clamp plate positioning support 106. The driving end of the clamp plate positioning motor 105 is connected with a clamp plate positioning wheel, and the clamp plate positioning synchronous belt is in transmission connection with the clamp plate positioning support 106. By controlling the rotation of the clamp plate positioning wheel, the clamp plate positioning motor 105 drives the clamp plate positioning synchronous belt to move, further bringing the clamp plate positioning support 106 closer to the middle of the silicon wafer conveying rail 101, aligning the position of a single-cell silicon wafer.

The front end of the silicon wafer conveying rail 101 is provided with an air-blowing cooling pipe 107, and the rear end of the silicon wafer conveying rail 101 is provided with an ion antistatic air knife 108. The air-blowing cooling pipe 107 performs cooling treatment, and the ion antistatic air knife 108 is responsible for electrostatic eliminating.

An AOI shaft 205 is arranged above the four-position turntable 201, and four AOI adsorption modules 206 are arranged on the periphery of the four-position turntable 201. The rotation of the AOI shaft 205 drives the four AOI adsorption modules 206 to transfer a single-cell silicon wafer counterclockwise.

A front track 308 and a rear track 309 are respectively arranged on both sides of the indexing disc assembly 302, and both the front track 308 and the rear track 309 drive a track belt to convey silicon wafers through a track motor; a first walking arm 310 and a second walking arm 311 are respectively arranged on both sides of the front track 308 and the side edge of the rear track 309, and both the first walking arm 310 and the second walking arm 311 are provided with a walking linear module. The driving end of the walking linear module is connected with a moving plate 312, and the inner end of the moving plate 312 is fixed with a negative pressure adsorption plate. The front track 308 is responsible for transferring a single-cell silicon wafer to the indexing disc assembly 302, the first walking arm 310 and the second walking arm 311 control the double half silicon wafers to move up and down on the indexing disc assembly 302, the negative pressure adsorption plate sucks up the half silicon wafer, and the rear track 309 is responsible for discharging the single-cell silicon wafer from the indexing disc assembly 302.

Both the X-axis module 307 and the Y-axis module include a motor mounting base 313, a module motor 314, an adjusting screw rod 315 and an adjusting sliding table 316. The module motor 314 is fixed on the motor mounting base 313, and the driving end of the module motor 314 is in transmission connection with the adjusting screw rod 315, wherein the adjusting screw rod 315 is in threaded connection with an adjusting nut of the adjusting sliding table 316, and the adjusting sliding table 316 slides along the length direction of the adjusting screw rod 315. The adjusting sliding table 316 has a connecting bearing 317, and the connecting bearing 317 slides on the adjusting sliding table 316. The moving direction of the connecting bearing 317 is perpendicular to the moving direction of the adjusting sliding table 316, and the edge of the UVW base 304 is locked in the connecting bearing 317. The two sets of X-axis modules 307 and one set of Y-axis modules jointly control the T-axis rotation of the UVW base 304 on one side. In the UVW alignment, two sets of X-axis modules 307 and one set of Y-axis in the above structure achieve X-axis translation, Y-axis translation and T-axis rotation of the upper probe holder 305 and the lower probe holder 306, meeting the alignment requirements.

The UVW base 304 is equipped with an upper linear module 318 and a lower linear module 319. The upper linear module 318 controls the vertical movement of the upper probe holder 305, while the lower linear module 319 controls the vertical movement of the lower probe holder 306. The upper linear module 318 makes the upper probe holder 305 press down on the upper surface of a single-cell silicon wafer, while the lower linear module 319 makes the lower probe holder 306 jack up and touch the grid line on the single-cell silicon wafer, so that the formed loop can be used for IV inspection.

The beneficial effects of Embodiment 1 of the present invention are as follows: A single-cell inspection all-in-one machine for solar silicon wafers is provided, and the single-cell inspection all-in-one machine for solar silicon wafers transports single-cell silicon wafers, successively undergoing AOI inspection and IV inspection. Operating automatically, it precisely connects the probe to the grid lines on the single-cell silicon wafers, enhancing inspection efficiency and increasing production capacity. The all-in-one multi-functional structure meets the demands of both front-end and back-end production.

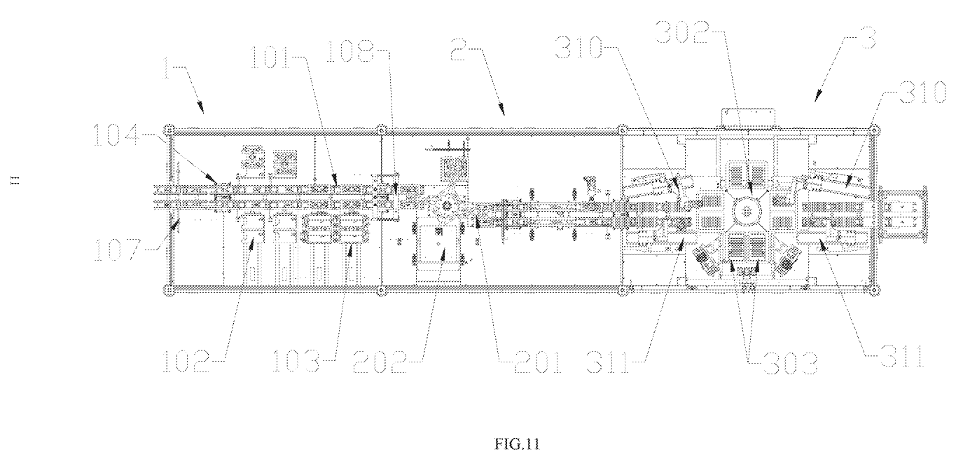

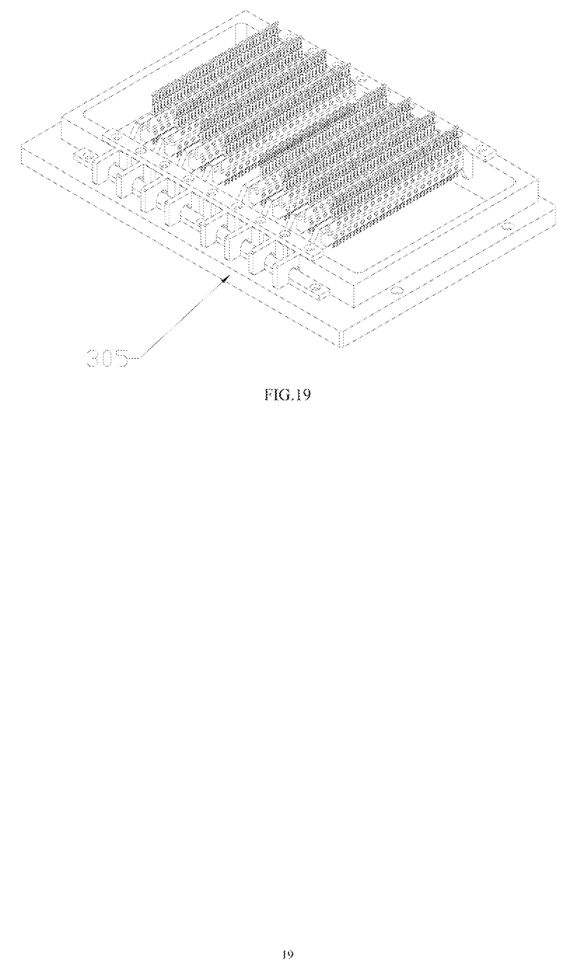

Referring to FIG.11- FIG.19,in Embodiment 2, the solar silicon wafer inspection all-in-one machine of the present invention is also used for detecting double half-cell silicon wafers. The solar silicon wafer inspection all-in-one machine comprises a front-end conveying rail 1, an AOI detection mechanism 2 and an IV detection mechanism 3, wherein the AOI detection mechanism 2 is located between the front-end conveying rail 1 and the IV detection mechanism 3.

Specifically, the front-end conveying rail 1 is provided with a silicon wafer conveying rail 101; the wafer conveying rail 101 includes two segments of half-cell conveying rails, wherein the two segments of half-cell conveying rails are arranged side by side on the front-end conveying rail 1. The two segments of half-cell conveying rails are used for conveying double half-cell silicon wafers, one of the double half-cell silicon wafers is arranged on one segment of half-cell conveying rail and the other half-cell silicon wafer is arranged on the other segment of half-cell conveying rail. The AOI detection mechanism 2 comprises a four-position turntable 201, a back AOI detection instrument assembly 202, a front AOI detection instrument assembly 203 and an AOI detection conveying rail 204, wherein the four-position turntable 201 is located at the front end of the AOI detection conveying rail 204, the back AOI detection instrument assembly 202 is located below the front end of the four-position turntable 201, and the front AOI detection instrument assembly 203 is installed above the AOI detection conveying rail 204; the IV detection mechanism 3 comprises a working platform 301, an indexing disc assembly 302 and two sets of detection mechanisms 303, wherein the indexing disc assembly 302 is located in the middle of the working platform 301, the two sets of detection mechanisms 303 are located on both sides of the position in front of the indexing disc assembly 302, and the detection mechanism 303 comprises a UVW base 304, an upper probe holder 305 and a lower probe holder 306, and the lower end of the UVW base 304 is provided with a UVW correction alignment assembly. The UVW correction alignment assembly includes two sets of X-axis modules 307 and one set of Y-axis modules. The upper probe holder 305 and the lower probe holder 306 respectively move on the UVW base 304 along the vertical direction. The lower probe holder 306 is equipped with a detection probe, and the two sets of detection mechanisms 303 move independently of each other.

After coming out of the sintering furnace, the printed double half-cell silicon wafers enter the silicon wafer conveying rail 101 respectively. At the end of the silicon wafer conveying rail 101, the AOI inspection mechanism 2 grabs the double half-cell silicon wafers onto the back AOI inspection instrument assembly 202 through the four-position turntable 201 for back inspection, and then turns to the AOI inspection conveying rail 204. The AOI inspection conveying rail 204 conveys the double half-cell silicon wafers to the front AOI inspection instrument assembly 203 for front inspection. Then, the indexing disc assembly 302 on the IV inspection mechanism 3 controls the double half-cell silicon wafers to reach the inspection mechanism 303, and under the joint action of two sets of X-axis modules 307 and one set of Y-axis modules, the lower probe holder 306 and the upper probe holder 305 on the UVW base 304 are controlled to align with the position of the double half-cell silicon wafers for IV inspection.

A temporary storage linear module is arranged on the front-end conveying rail 1, and a temporary storage frame 102 is arranged at the driving end of the temporary storage linear module. The temporary storage frame 102 moves laterally on the side of the silicon wafer conveying rail 101, and the temporary storage frame 102 moves laterally on the side of the front-end conveying rail 1. When the temporary storage linear module on one side is fully loaded, the other side begins to be placed, and the fully loaded side can be manually discharged.

The front-end conveying rail 1 is provided with a feeding linear module, and the driving end of the feeding linear module is connected with a feeding longitudinal module, wherein the feeding longitudinal module moves laterally on the side of the silicon wafer conveying rail 101, and the driving end of the feeding longitudinal module is connected with a feeding rack 103, wherein the feeding rack 103 moves up and down in the vertical direction. After the feeding linear module approaches the front-end conveying rail 1, the upper and lower transverse modules above the front-end conveying rail 1 control the upper and lower adsorption modules to suck up a half-cell silicon wafer on the feeding rack 103 and put it into the front-end conveying rail 1. In order to ensure the height of the uppermost silicon wafer, the feeding longitudinal module controls the feeding rack 103 to raise a silicon wafer position until all the silicon wafers on the feeding rack 103 are taken away, and the feeding linear module leaves the front-end conveying rail 1 laterally, and then repeatedly approaches the front-end conveying rail 1 for feeding after filling the silicon wafer.

A clamp plate positioning mechanism 104 is arranged in the middle of the silicon wafer conveying rail 101. The clamp plate positioning mechanism 104 comprises a clamp plate positioning motor 105, a clamp plate positioning synchronous belt and a clamp plate positioning support 106. The driving end of the clamp plate positioning motor 105 is connected with a clamp plate positioning wheel, and the clamp plate positioning synchronous belt is in transmission connection with the clamp plate positioning support 106. By controlling the rotation of the clamp plate positioning wheel, the clamp plate positioning motor 105 drives the clamp plate positioning synchronous belt to move, further bringing the clamp plate positioning support 106 closer to the middle of the silicon wafer conveying rail 101, aligning the position of a half-cell silicon wafer.

The front end of the silicon wafer conveying rail 101 is provided with an air-blowing cooling pipe 107, and the rear end of the silicon wafer conveying rail 101 is provided with an ion antistatic air knife 108. The air-blowing cooling pipe 107 performs cooling treatment, and the ion antistatic air knife 108 is responsible for electrostatic eliminating.

An AOI shaft 205 is arranged above the four-position turntable 201, and four AOI adsorption modules 206 are arranged on the periphery of the four-position turntable 201. The rotation of the AOI shaft 205 drives the four AOI adsorption modules 206 to transfer a half-cell silicon wafer counterclockwise.

Two front tracks 308 and two rear tracks 309 are respectively arranged on both sides of the indexing disc assembly 302, and both the front track 308 and the rear track 309 drive a track belt to convey silicon wafers through a track motor; a first walking arm 310 and a second walking arm 311 are arranged on both sides of the front track 308 and both sides of the rear track 309, and both the first walking arm 310 and the second walking arm 311 are provided with a walking linear module. The driving end of the walking linear module is connected with a moving plate 312, and the inner end of the moving plate 312 is fixed with a negative pressure adsorption plate. Two front tracks 308 are responsible for transferring double half-cell silicon wafers to the indexing disc assembly 302, the first walking arm 310 and the second walking arm 311 control the double half silicon wafers to move up and down on the indexing disc assembly 302, the negative pressure adsorption plate sucks up the half silicon wafer, and two rear tracks 309 are responsible for discharging the double half-cell silicon wafers from the indexing disc assembly 302.

Both the X-axis module 307 and the Y-axis module include a motor mounting base 313, a module motor 314, an adjusting screw rod 315 and an adjusting sliding table 316. The module motor 314 is fixed on the motor mounting base 313, and the driving end of the module motor 314 is in transmission connection with the adjusting screw rod 315, wherein the adjusting screw rod 315 is in threaded connection with an adjusting nut of the adjusting sliding table 316, and the adjusting sliding table 316 slides along the length direction of the adjusting screw rod 315. The adjusting sliding table 316 has a connecting bearing 317, and the connecting bearing 317 slides on the adjusting sliding table 316. The moving direction of the connecting bearing 317 is perpendicular to the moving direction of the adjusting sliding table 316, and the edge of the UVW base 304 is locked in the connecting bearing 317. The two sets of X-axis modules 307 and one set of Y-axis modules jointly control the T-axis rotation of the UVW base 304 on one side. In the UVW alignment, two sets of X-axis modules 307 and one set of Y-axis in the above structure achieve X-axis translation, Y-axis translation and T-axis rotation of the upper probe holder 305 and the lower probe holder 306, meeting the alignment requirements.

The UVW base 304 is equipped with an upper linear module 318 and a lower linear module 319. The upper linear module 318 controls the vertical movement of the upper probe holder 305, while the lower linear module 319 controls the vertical movement of the lower probe holder 306. The upper linear module 318 makes the upper probe holder 305 press down on the upper surface of a half-cell silicon wafer, while the lower linear module 319 makes the lower probe holder 306 jack up and touch the grid line on the half-cell silicon wafer, so that the formed loop can be used for IV inspection.

The beneficial effects of Embodiment 2 of the present invention are as follows: A double half-cell inspection all-in-one machine for solar silicon wafers is provided, and the double half-cell inspection all-in-one machine for solar silicon wafers simultaneously transport double half-cell silicon wafers, successively undergoing AOI inspection and IV inspection. Operating automatically, it precisely connects the probe to the grid lines on the double half-cell silicon wafers, enhancing inspection efficiency and increasing production capacity. The all-in-one multi-functional structure meets the demands of both front-end and back-end production.

It should be noted that the above specific implementation methods merely represent preferred embodiments of the present invention and the technical principles employed. Within the scope of the disclosed technology, any modifications or substitutions readily conceivable by those skilled in the art should be encompassed within the scope of protection of the present invention.

What is claimed is:

1. A solar silicon wafer inspection all-in-one machine, wherein it comprises a front-end conveying rail, an AOI detection mechanism and an IV detection mechanism, and the AOI detection mechanism is positioned between the front-end conveying rail and the IV detection mechanism;
the front-end conveying rail is provided with a silicon wafer conveying rail, and the silicon wafer conveying rail is used for conveying silicon wafers;
the AOI inspection mechanism comprises a four-position turntable, a back AOI inspection instrument assembly, a front AOI inspection instrument assembly and an AOI inspection conveying rail; the four-position turntable is located at the front end of the AOI inspection conveying rail, and the back AOI inspection instrument assembly is located below the front end of the four-position turntable; the front AOI detection instrument assembly is installed above the AOI detection conveying rail;
the IV detection mechanism comprises a working platform, an indexing disc assembly and a detection mechanism; the indexing disc assembly is located in the middle of the working platform, and the detection mechanism is located in front of the indexing disc assembly; the detection mechanism includes a UVW base, an upper probe holder and a lower probe holder; the lower end of the UVW base is installed with a UVW correction alignment assembly; the UVW correction alignment assembly includes two sets of X-axis modules and one set of Y-axis modules; the upper probe holder and the lower probe holder move vertically on the UVW base respectively and the detection probes are installed on the upper probe holder and the lower probe holder.

2. A solar silicon wafer inspection all-in-one machine as claimed in claim 1, wherein a temporary storage linear module is arranged on the front-end conveying rail, a temporary storage frame is arranged at the driving end of the temporary storage linear module, and the temporary storage frame moves laterally on the side of the silicon wafer conveying rail.

3. A solar silicon wafer inspection all-in-one machine as claimed in claim 1, wherein the front-end conveying rail is provided with a feeding linear module, and the driving end of the feeding linear module is connected with a feeding longitudinal module; the feeding longitudinal module moves laterally on the side of the silicon wafer conveying rail, the driving end of the feeding longitudinal module is connected with a feeding rack, and the feeding rack moves up and down in the vertical direction.

4. A solar silicon wafer inspection all-in-one machine as claimed in claim 1, wherein a clamp plate positioning mechanism is arranged in the middle of the silicon wafer conveying rail, and the clamp plate positioning mechanism comprises a clamp plate positioning motor, a clamp plate positioning synchronous belt and a clamp plate positioning support; the driving end of the clamp plate positioning motor is connected with a clamp plate positioning wheel; the clamp plate positioning synchronous belt is in transmission connection with the clamp plate positioning wheel and the clamp plate positioning support is installed on the clamp plate positioning synchronous belt.

5. A solar silicon wafer inspection all-in-one machine as claimed in claim 1, wherein the front end of the silicon wafer conveying rail is provided with an air-blowing cooling pipe, and the rear end of the silicon wafer conveying rail is provided with an ion antistatic air knife.

6. A solar silicon wafer inspection all-in-one machine as claimed in claim 1, wherein an AOI shaft is arranged above the four-position turntable, and four AOI adsorption modules are arranged on the periphery of the four-position turntable.

7. A solar silicon wafer inspection all-in-one machine as claimed in claim 1, wherein both sides of the indexing disc assembly are respectively provided with a front track and a rear track, and both the front track and the rear track drive a track belt through a track motor to convey silicon wafers.

8. A solar silicon wafer inspection all-in-one machine as claimed in claim 7, wherein a first walking arm and a second walking arm are respectively installed on both sides of the front track and the side edge of the rear track, and a walking linear module is arranged on both the first walking arm and the second walking arm, and a moving plate is connected to the driving end of the walking linear module, and a negative pressure adsorption plate is fixed to the inner end of the moving plate.

9. A solar silicon wafer inspection all-in-one machine as claimed in claim 1, wherein the X-axis module and the Y-axis module both comprise a motor mounting base, a module motor, an adjusting screw rod and an adjusting sliding table; the module motor is fixed on the motor mounting base, the driving end of the module motor is in transmission connection with the adjusting screw rod, and the adjusting screw rod is in threaded connection with the adjusting nut of the adjusting sliding table; the adjusting sliding table slides along the length direction of the adjusting screw rod, and the adjusting sliding table is provided with a connecting bearing; the connecting bearing slides on the adjusting sliding table, the moving direction of the connecting bearing is perpendicular to that of the adjusting sliding table, and the edge of the UVW base is locked in the connecting bearing; two sets of X-axis modules and one set of Y-axis modules jointly control the T-axis rotation of the UVW base on one side.

10. A solar silicon wafer inspection all-in-one machine as claimed in claim 1, wherein the UVW base is provided with an upper linear module and a lower linear module; the upper linear module controls the vertical movement of the upper probe holder and the lower linear module controls the vertical movement of the lower probe holder.

11. A solar silicon wafer inspection all-in-one machine as claimed in claim 1, wherein the silicon wafer conveying rail is a single-cell conveying rail, and the single-cell conveying rail is used for conveying single-cell silicon wafers.

12. A solar silicon wafer inspection all-in-one machine as claimed in claim 1, wherein the silicon wafer conveying rail comprises two segments of half-cell conveying rails; two segments of the half-cell conveying rails are arranged side by side on the front-end conveying rail and used for conveying double half-cell silicon wafers.
